(19) United States
(12) Patent Application Publication
(10) Pub. No.: US 2011/0255701 A1
(43) Pub. Date: Oct. 20, 2011

(54) METHOD FOR DYNAMICALLY ADJUSTING THE SPECTRAL CONTENT OF AN AUDIO SIGNAL

(76) Inventors: J. CRAIG OXFORD, Nashiville, TN (US); D. Michael Shields, St. Paul, MN (US)

(21) Appl. No.: 13/076,662

(22) Filed: Mar. 31, 2011

Related U.S. Application Data
(63) Continuation-in-part of application No. 11/633,908, filed on Dec. 5, 2006.
Application No. 11/633,908 is a continuation-in-part of application No. 11/653,510, filed on Jan. 16, 2007.
Application No. 11/653,510 is a continuation-in-part of application No. 11/633,908, filed on Dec. 5, 2006.
(60) Provisional application No. 60/794,293, filed on Apr. 22, 2006.
(60) Provisional application No. 60/794,293, filed on Apr. 22, 2006.

(51) Int. Cl. H03G 3/00

(52) U.S. Cl. 381/61

(57) ABSTRACT

Circuit and associated methods for dynamically adjusting the spectral content of an audio signal, which increases the harmonic content through the systematic introduction of amplitude asymmetry. In one embodiment, the method comprises a spectral modification of an analog audio signal in which the high-frequency content is reduced as a function of the signal amplitude and spectral distribution. The audio signal is subjected to a complementary pre-emphasis and de-emphasis of the high frequencies.

This application is a continuation-in-part of and claims the benefit of U.S. Utility application Ser. No. 11/633,908, filed Dec. 5, 2006, which claims benefit of and priority to U.S. Provisional Patent Application No. 60/794,293, filed Apr. 22, 2006. The application also is a continuation-in-part of U.S. Utility application Ser. No. 11/653,510, filed Jan. 16, 2007, which is a continuation-in-part of U.S. Utility application Ser. No. 11/633,908, filed Dec. 5, 2006, which claims benefit of and priority to U.S. Provisional Patent Application No. 60/794,293, filed Apr. 22, 2006. The specification, figures and complete disclosures of U.S. Provisional Patent Application No. 60/794,293 and U.S. Utility application Ser. Nos. 11/633,908; 11/653,510; and 11/708,452 are incorporated herein by specific reference for all purposes.

### FIELD OF INVENTION

The present invention relates to an electronic circuit and related methods for improving the sound from audio playback, and more particularly an electronic circuit capable of introducing predictable and controllable harmonic distortion that increases with increased signal amplitude.

### BACKGROUND OF THE INVENTION

The reproduction of music recordings is typically performed by a chain of equipment consisting of at least a playback device for the type of recording at hand, an amplifier and a loudspeaker. There is abundant anecdotal evidence that many listeners prefer that the music reproduction chain should include a vacuum-tube based amplifier, which should also be preferably single-ended (as opposed to push-pull). Other factors being equal, the performance of such an amplifier will be objectively inferior to almost any other commonly used vacuum-tube or solid-state push-pull or topologically symmetrical amplifier.

The stated subjective preference nevertheless remains. It is important to understand why this might be so. In the production of music whether by electric guitar or symphony orchestra, preferences about musical instruments are influenced by the harmonic structure of the sound, which they produce. This is a very fundamental aspect of timbre. Some orchestras will even limit the acceptable historical provenance of musicians' instruments based on the tonal qualities associated with particular periods of manufacture.

This importance of harmonic structure pertains equally to reproduced music. The reproduction of music is certainly not the same thing as its original production and it might be hoped that in the ideal case the reproducing process would be merely a transparent vessel for the original sounds. Alas, this is not the case, nor is it likely to be so in the foreseeable future. Refinement of the measured performance of reproducing equipment is not always accompanied by an audible result, which is musically convincing. There are many reasons why this might be the case.

The objective inferiority of the single-ended vacuum-tube amplifier takes the form of higher numerical distortion. Measured as undesired harmonic content such an amplifier will exhibit a total harmonic distortion (THD) typically many times that of a symmetrical or push-pull amplifier. It should be pointed out that THD is a single-number expression, which does not quantify the spectral content of the distortion. Harmonic distortion consists of additions to the fundamental tone at new frequencies, which are integral multiples of the tone. For example an input signal to an amplifier at 1 kHz will result in an output signal which contains the original 1 kHz tone plus smaller amounts of 2,3,4 etc. kHz, as shown in FIG. 1. The THD is simply the square root of the sum of the squares of the harmonic amplitudes divided by the total amplitude. Multiplied by 100, the THD is usually stated in percent.

The use of this single-number rating provides a coarsely useful figure of merit for an amplifier but it may be seriously misleading because it does not qualitatively describe the distortion. Evidence of this is the often-stated listener preference for amplifiers with higher THD. Push-pull or symmetrical amplifiers are an example of this difficulty. The THD is reduced in these amplifiers because the topological symmetry causes the even-order harmonics (2nd, 4^{th}, and so on) to be cancelled. This results in an “empty” harmonic spectrum in which only the odd-order harmonics (3rd, 5^{th}, and so on) are present as shown in FIG. 2. In musical terms, the even harmonics are “consonant” and the odd harmonics are “dissonant.” Since in practical amplifiers the distortion is never zero, it would be better if the unavoidable residual distortion could be consonant rather than dissonant.

It is a further characteristic of amplifiers generally that the onset of whatever distortion occurs is progressive with signal amplitude. Extremely “clean” amplifiers may show very little distortion until they closely approach overload at which point the distortion increases almost catastrophically. Single-ended vacuum-tube amplifiers on the other hand have a very progressive distortion characteristic with signal amplitude. Push-pull vacuum-tube amplifiers are somewhere in between. Often this is related to the use of negative feedback, which is generally less in vacuum-tube designs and more in solid-state designs. The difference is illustrated in FIG. 3.

Another aspect of amplifiers that affects the structure of the distortion is the use of negative feedback. The application of negative feedback reduces the measured distortion in any amplifier. In practice, the reduction of distortion components by applying feedback does not uniformly reduce these components. The low-order, i.e. 2nd and 3^{rd} order, harmonics will be reduced more effectively than the higher order harmonics. The consequence is that, even though the THD is reduced, the remaining distortion spectrum consists mainly of high order harmonics. This type of distortion is particularly unpleasant because it is spectrally far removed from the stimulus and therefore not masked by it. The confluence of subjectively disagreeable results occurs when symmetrical circuits are combined with large amounts of negative feedback. What results is a distortion spectrum, which consists almost entirely of odd high-order products as shown in FIG. 4. Perversely, these circuits usually produce the lowest measured THD.

There are several problems, which can be identified from the foregoing discussion. First, the use of vacuum tubes in modern equipment is undesirable if for no other reason than that reliable sources of supply do not exist. Second, the use of single-ended topologies in amplifiers, which must provide significant power output, is a tremendous disadvantage because of the necessity to operate such a circuit in class A bias. This condition of operation is unacceptably inefficient from both an environmental and engineering perspective. Third, the avoidance of negative feedback in a power amplifier results in a high source impedance of the output, which is contrary to the design requirements of most loudspeaker systems, which will be driven by the amplifier.

It should be pointed out that in the electric musical instrument industry as well as the recording industry there have been numerous attempts to emulate “tube” sound with solid-state circuits. A review of these attempts shows that they generally seem to misunderstand what they are trying to emulate. They mostly concern themselves with the notion of “soft clipping” in an attempt to render the overload behavior of high-feedback solid-state circuits less abrupt. But this approach only indirectly addresses the question of harmonic structure. Most of the prior art along these lines generally processes the signal symmetrically giving rise mainly to odd harmonics. Also, the processing usually takes the form of inverse-parallel diodes either acting as direct shunt elements across the signal path or as series elements in a feedback loop. The use of symmetrical clipping inside a feedback loop is directly contraindicated in view of the discussion above. Furthermore the use of only one or two diodes across their exponential “knee” makes the action too abrupt to approach the more gradual onset of distortion illustrated in the upper curve of FIG. 3. Accordingly, most of the prior art is implemented in a manner which requires user adjustment of the operating parameters.

A similar issue may be found relative to the media used for audio reproduction. From the beginning of the digital era all the way up to the present time, there are a significant number of critical listeners who prefer the sound of the older media, LPs in particular, over that of compact discs (CDs). While there are many parts to the discussion of why this is true, the single most gross objective difference between LPs and CDs is the comparatively deficient high-frequency power spectrum of the LP due to the adaptation of the pre-emphasis. Prior to the introduction of the compact disc as the primary consumer distribution medium for audio, there were three primary delivery media: FM broadcast; tape cassette; and LP (long playing) record. These media all have one technical characteristic in common: they are pre-emphasized. This means that during recording or transmission the high frequencies are boosted. During receiving or playback the high frequencies are attenuated by a complementary amount. The result, in principle, is flat response (i.e., uniform amplitude vs. frequency). The reason for doing this is that the inherent noise in the information channel is reduced due to the de-emphasis.

The underlying assumptions for choosing the amount of pre-emphasis and de-emphasis are old. The basic characteristics date back to the 1940s. At that time, close placement of microphones was not common in music recording, and the microphones generally had deficient high-frequency response. As a result, the application of pre-emphasis at the originating end didn't usually cause a problem. As microphones improved and studio recording techniques favored closer microphone placement, the high-frequency power density of the music signals to be recorded or broadcast became much greater. The pre-emphasis became a problem: in order to avoid high-frequency overload it was necessary to reduce the overall volume level. In terms of signal-to-noise ratio, this largely defeated the whole point of the pre-emphasis/de-emphasis system. By this time, however, the entire installed base of FM receivers, record players and cassette machines incorporated the fixed de-emphasis, so the pre-emphasis could not be dispensed with.

One solution to this problem at the source end (i.e., broadcasting and disc cutting) was to devise a system of adaptive pre-emphasis. This means that, during those signals which do not overload the pre-emphasis, it is fully applied. As the high-frequency content of the signal increases, the pre-emphasis is progressively reduced to prevent overload. When this is done correctly, the result is generally not perceived as an impairment to the audio quality. Objectively, however, the result is a system in which loud passages usually have a reduced amount of high-frequency power. This technique was not widely used in magnetic tape recording because the high-frequency overload characteristics of tape are less abrupt and therefore less audible than for other media.

### SUMMARY OF THE INVENTION

In various embodiments, the present invention seeks to restore the perceptual and emotional elements lost to technical processes. In one embodiment, the instant apparatus is an electronic circuit that can be arranged to process an audio signal so as to introduce a predictable and controllable harmonic distortion, which is negligible at small signal amplitudes and increases progressively at larger signal amplitudes. Further, no negative feedback is present in the signal path of this processor and the distortion spectrum is monotonic with frequency. In addition, the signal amplitude, which is lost in the process, can be restored without affecting the spectrum.

Recent developments in power amplifier technology have resulted in the availability of very high performance Class-D amplifiers, which operate with high efficiency and very low residual distortion. It is contemplated that an optimum use of the signal process to be described may be in conjunction with such Class-D amplifiers as well as the usual types of linear continuous-time amplifiers.

### BRIEF DESCRIPTION OF THE DRAWINGS

FIG. 1 is a graph of an exemplary output signal.

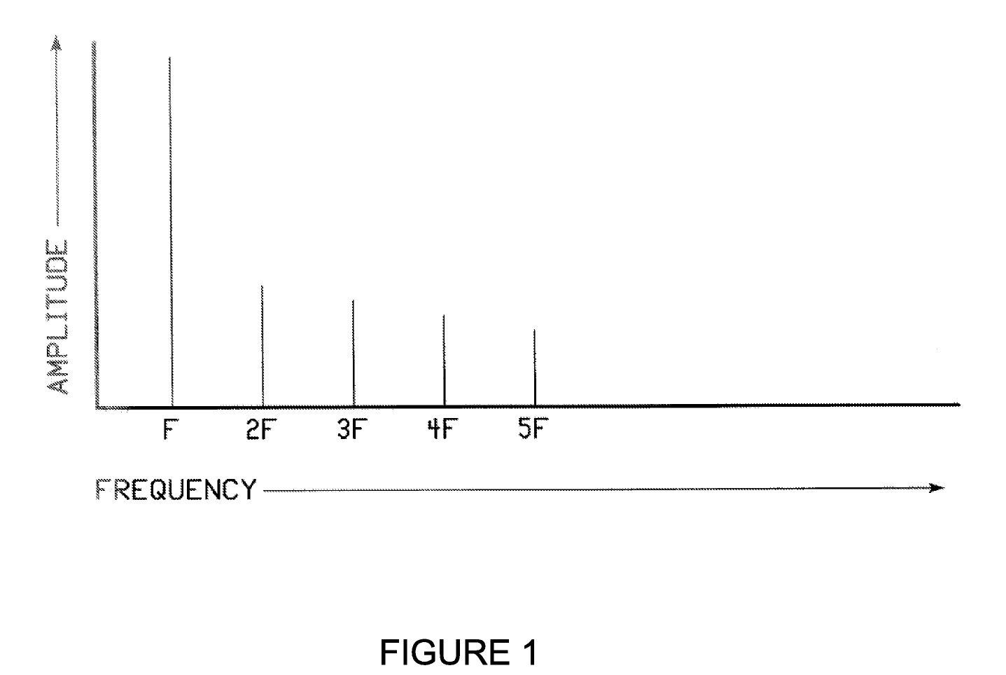

FIG. 2 shows a graph of an exemplary odd-order harmonic spectrum output signal.

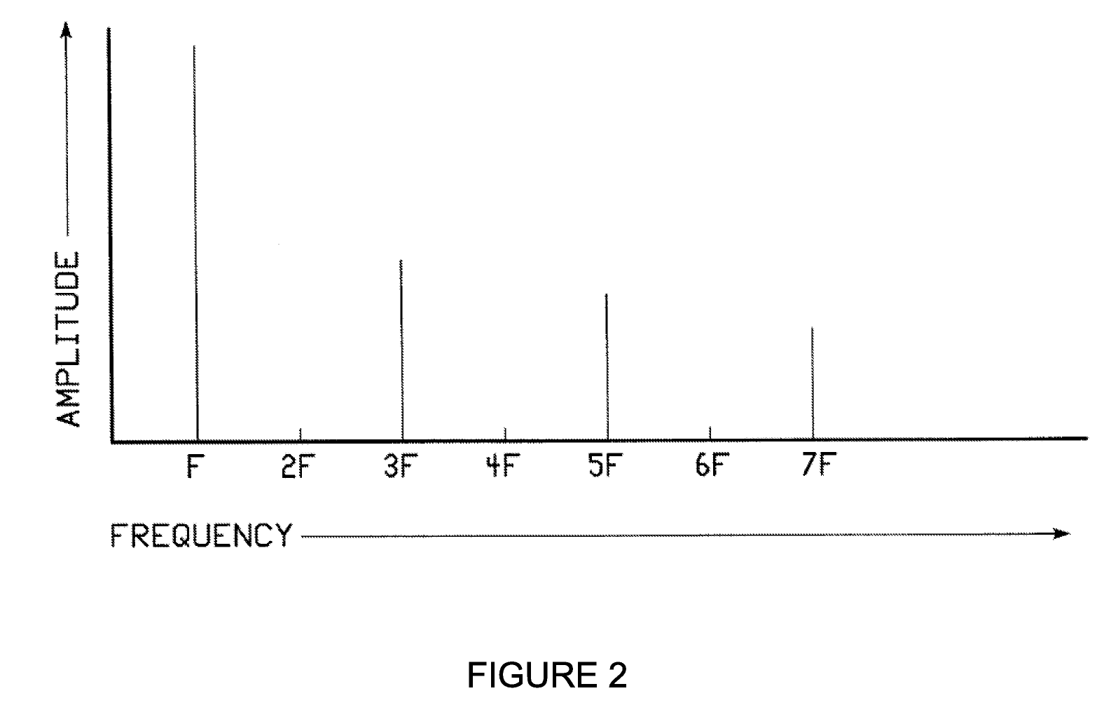

FIG. 3 shows an exemplary graph of total harmonic distortion vs. power output for different amplifiers.

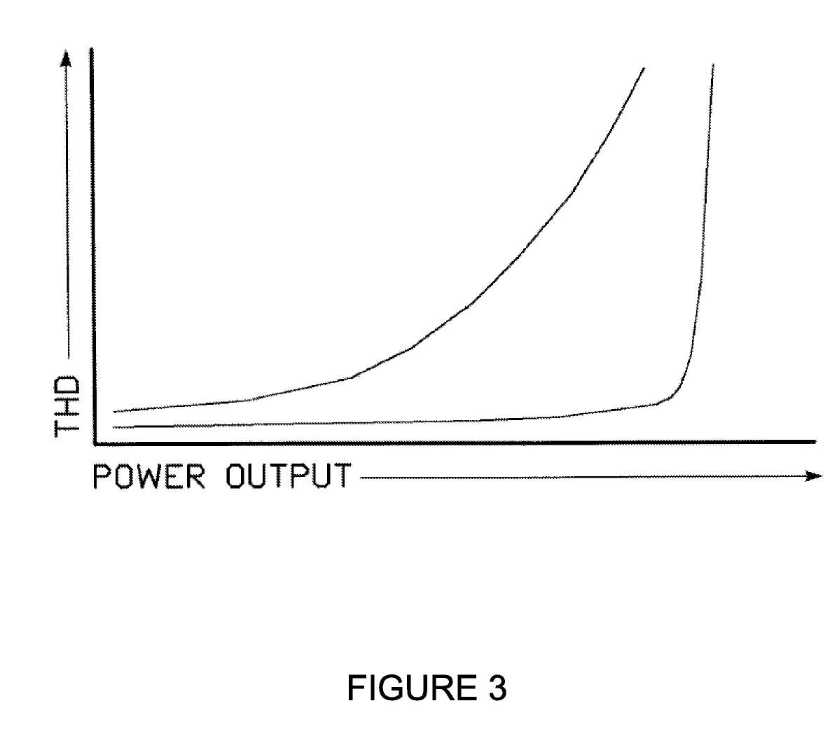

FIG. 4 shows a graph of an exemplary output signal with high-order products.

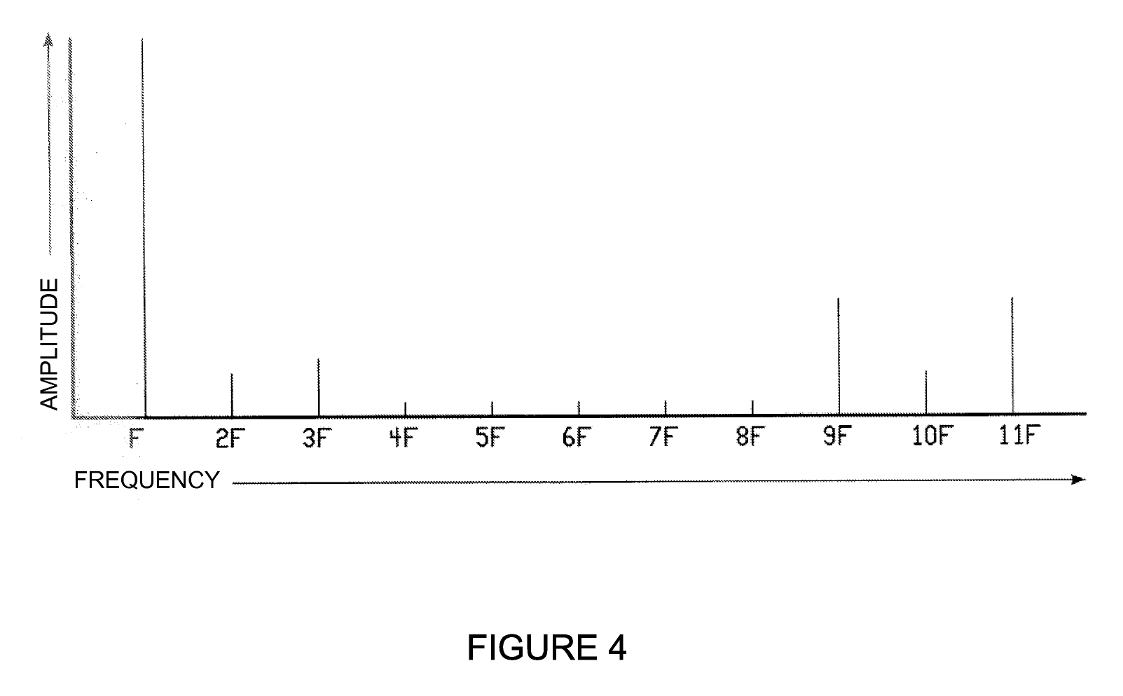

FIG. 5 shows an example of a circuit comprising an input buffer, output buffer, a constant-current source, and a non-linear element.

FIG. 6 shows a diagram of an example of a constant current source.

FIG. 7 shows a diagram of an example of an input buffer.

FIG. 8 shows a diagram of examples of an output buffer.

FIG. 9 shows a diagram of an example of a non-linear element comprising a diode string.

FIG. 10 is a diagram of an example of a diode string with symmetrical clipping.

FIG. 11 is a graph showing complementary fixed pre-emphasis and fixed de-emphasis of high frequencies.

FIG. 12 shows multiple variable pre-emphasis curves along with a fixed de-emphasis.

FIG. 13 is a graph showing an example of output spectra resulting from superposition of adaptive pre-emphasis and fixed de-emphasis.

FIG. 14 is a diagram of a device in accordance with an exemplary embodiment of the present invention.

FIG. 15 is a diagram of a device in accordance with another exemplary embodiment of the present invention.

FIG. 16 is a diagram of a device in accordance with another exemplary embodiment of the present invention.

FIG. 17 is a diagram of a de-emphasis filter circuit in accordance with another exemplary embodiment of the present invention.

FIG. 18 is a diagram of the integrator circuit of FIG. 15.

### DETAILED DESCRIPTION OF THE INVENTION

In various exemplary embodiments, the present invention comprises circuits and associated methods to perform a spectral modification of an audio signal, including an analog audio signal. In general, the high-frequency content is reduced as a function of the signal amplitude and spectral distribution.

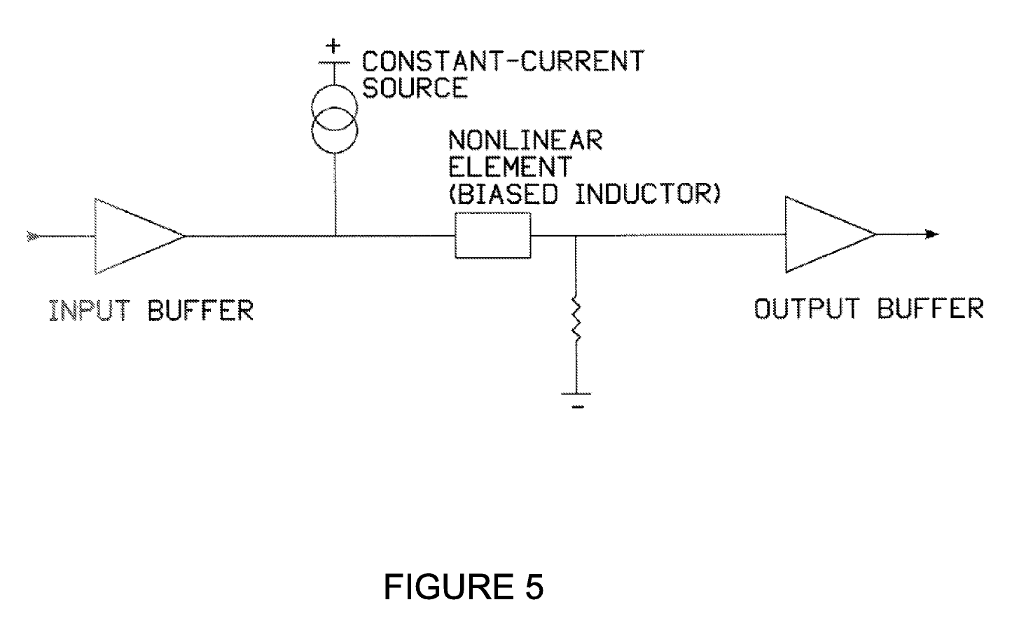

FIG. 5 shows an exemplary embodiment of a basic circuit, comprising an input buffer, an output buffer, a constant-current source, and a nonlinear element which consists of an inductor. The audio signal is AC-coupled at both ends of the nonlinear element and it is forward-biased by the constant-current source.

In this embodiment, the circuit is intentionally unsymmetrical. As the audio signal voltage goes positive the core of the inductor begins to saturate which reduces its impedance at audio frequencies and causes an increase in the instantaneous value of the audio signal at its output. When the audio signal goes negative, this does not occur and the resulting asymmetry causes the generation of a monotonic harmonic spectrum.

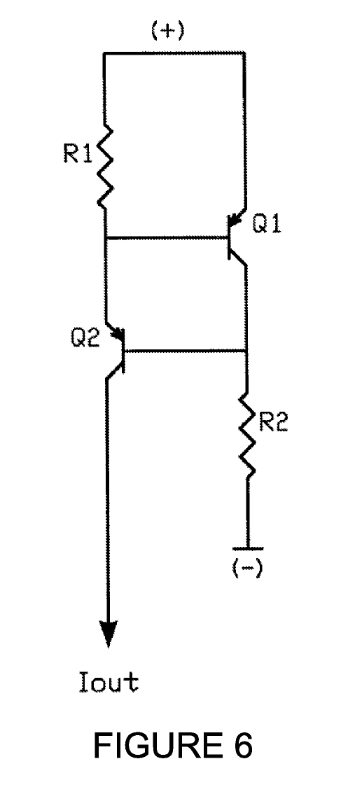

As shown in FIG. 6, the constant current source in one exemplary embodiment is a ring source. Other topologies such as a Widlar current mirror can also be used. The influence of the current source on the circuit operation has been investigated and the ring source has been found to be optimum when implemented with transistors of high beta. This is because it maintains a very high AC impedance over the required frequency range and over the voltage range for which the rest of the circuit is useful. In this embodiment, the current value, which is supplied by the constant-current source, is a basic operating parameter of the circuit. For a given range of signal amplitudes, the onset and quantity of harmonic distortion, which is generated, can be adjusted by varying the bias current from the constant-current source.

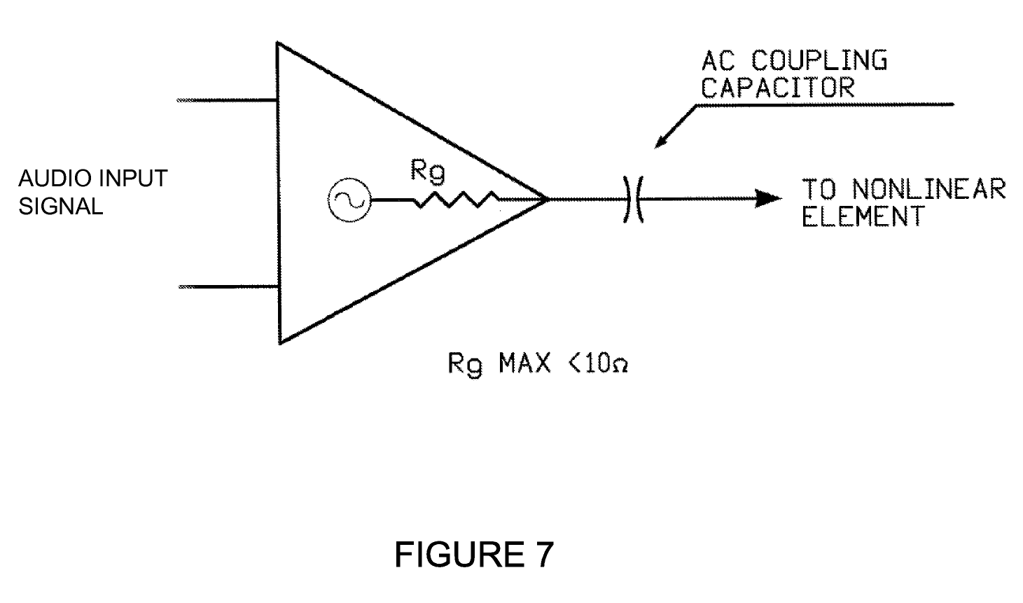

The input buffer of this embodiment present invention is shown in FIG. 7. This stage defines the source impedance, which drives the inductor. Because the operation is based upon an instantaneous signal-dependent impedance change in the inductor, it follows that if the source resistance is too high the desired nonlinearity will be proportionally less and the intended circuit function will be diminished. In a preferred embodiment, a source resistance may be held to less than 10 Ohms. If a driving amplifier with sufficiently low source resistance is available, then the input buffer could be eliminated. The output of the buffer must be AC-coupled to the input of the inductor with the coupling capacitor value large enough to prevent restriction of low frequencies due to the input impedance of the inductor. The exact value of the input impedance depends on the bias current supplied from the constant-current source. Anyone skilled in the art of circuit design may determine the coupling capacitor value.

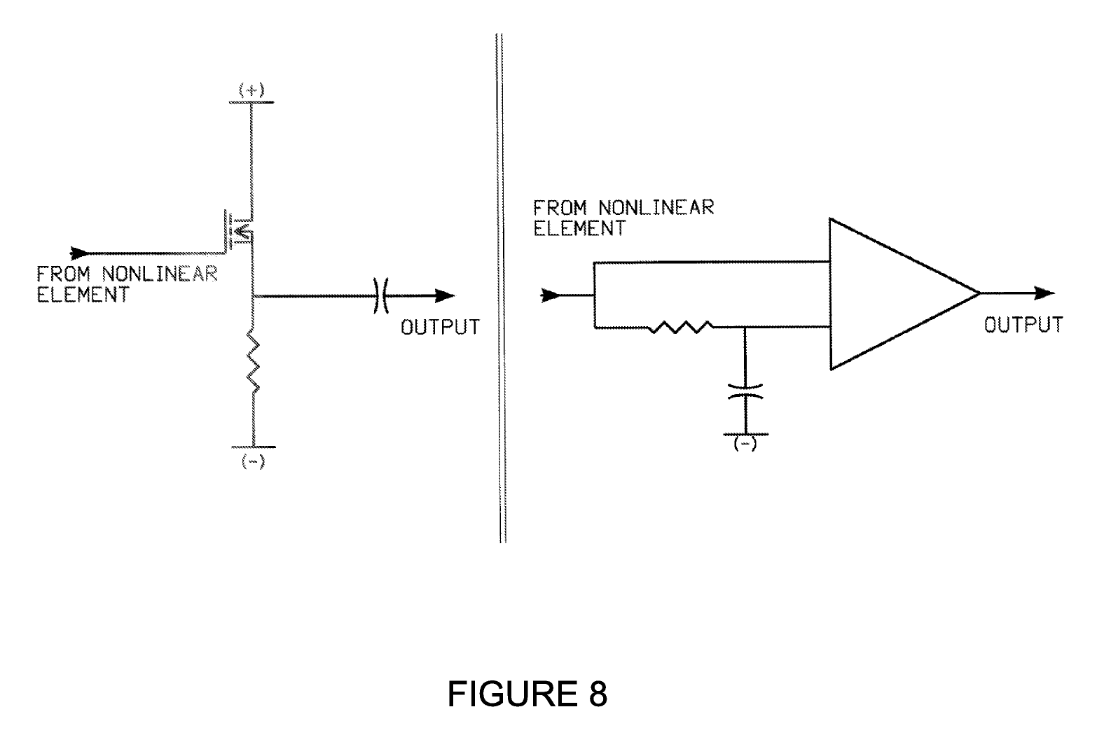

An output buffer of one embodiment of the present invention is shown in FIG. 8. This stage prevents the downstream circuit from placing an undefined load on the inductor. In a preferred embodiment as shown, the buffer is a simple MOSFET source-follower, which is DC-coupled to the output of the inductor. Since the buffer will have a standing DC voltage on its source terminal it may be necessary to AC couple from the buffer to the following circuitry.

In an alternative embodiment of the output buffer, the signal may be returned to a ground-centered voltage by integrating the DC voltage at the output of the inductor at a sub-audio rate and subtracting it from the signal in a differential amplifier. Both embodiments are shown.

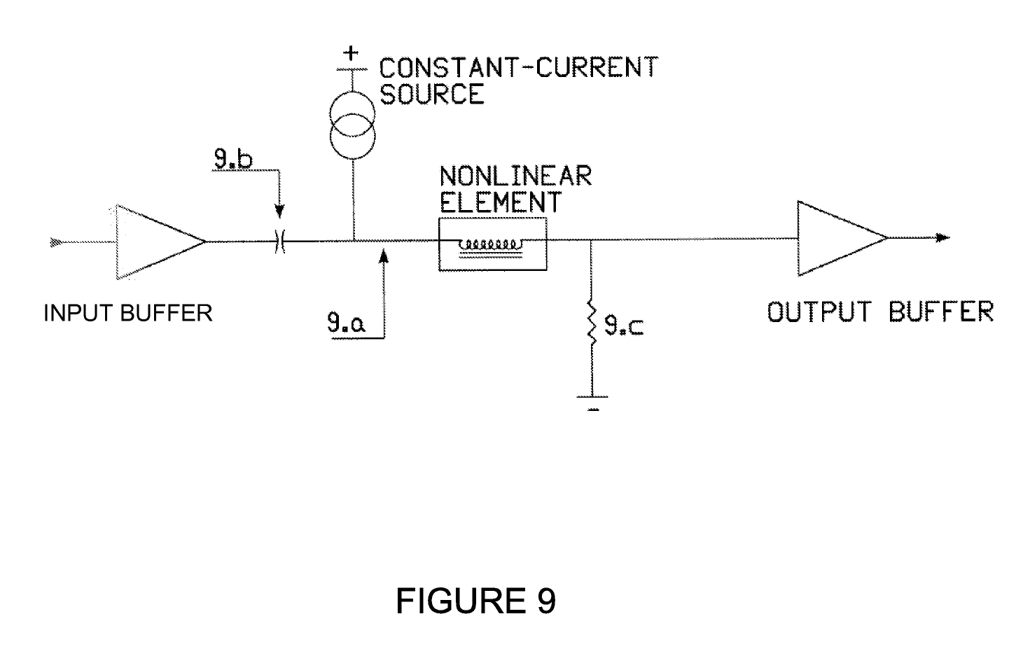

FIG. 9 shows an embodiment of a nonlinear inductor. The application of a constant-current bias to the inductor assures that it will produce the desired odd-even monotonic harmonic series as it approaches magnetic saturation. If the inductor is not biased, then only odd harmonics are produced, which is not desirable. The constant-current source is shown in FIG. 6. An input buffer is as shown in FIG. 7. An output buffer is as shown in FIG. 8.

Operation of the inductor is as follows: an alternating current flows through the inductor due to the application of an alternating voltage at 9.a from the buffer amplifier. The current flow is from the buffer amplifier via coupling capacitor 9.b through the inductor and through the load resistor 9.c. The resulting voltage across load resistor 9.c is taken as the output signal via the output buffer.

Current flow in an inductor produces a magnetizing force in the winding, which in turn produces a concentrated magnetic flux in the core. The total current is composed of the AC audio signal plus the DC constant-current. This causes more magnetic flux in the core when the AC signal is in the same direction as the DC bias, and less flux in the core when the AC signal is in opposition to the DC bias. Assuming the magnitudes of the currents are appropriately scaled, the core of the inductor will approach saturation more quickly for one polarity of the AC signal than for the other polarity. As the core of an inductor approaches saturation, the value of the inductance falls. Since the impedance of an inductor is directly proportional to the inductance, the series impedance of the signal path will vary asymmetrically through the signal cycle. The resulting asymmetry accomplishes the desired spectral alteration. The degree of asymmetry is directly proportional to the constant-current bias and may therefore be adjusted by changing the bias current. The rate of onset of the asymmetry is governed by the magnetic properties of the core, and by the range of AC signal amplitude. A core with a gradual magnetic saturation characteristic will provide a gradual increase in harmonic production. Such a core may be fabricated from powdered iron or Molypermalloy material. A core with an abrupt saturation characteristic will provide a more abrupt onset of harmonic production. Such a core may be fabricated from ferrite or amorphous metal.

The required inductance can be determined by considering the load resistance, R (item 9.c in FIG. 9). The impedance magnitude of an inductor varies directly with frequency. The result of this is that there will be a low-pass filter effect on the signal, i.e., the higher frequencies will be progressively attenuated. A criterion may be arbitrarily chosen for the allowable attenuation at the highest frequency of interest. In an audio application the attenuation should probably not exceed 1 dB at 15 kHz. Given this requirement, the reactance of the inductor should be about 0.12 times the value of R. For example, if R=1000 Ohms, the inductive reactance should be about 120 Ohms at 15 kHz.

Since X_{L}=2πFL where:

X_{L}=Inductive reactance in Ohms

F=frequency in Hz

L=inductance in Henries (H)

the required inductance will be about 1.3 mH. If the inductance index A_{L} (in nH/n²) of the intended core is known, the number of turns (n) in the winding can be calculated as n=sqrt(L/A_{L}), where for this equation L is expressed in mH.

The required bias current can be determined by the application of the relationship

H=(nI)/(0.8 Le) where:

H=magnetizing force in Oersteds

n=number of turns of wire in the winding

Le=effective magnetic path length of the core in cm

I=DC bias current in Amperes

and by the relationship B=uH where:

B=magnetic flux density in Gauss

u=average magnetic permeability of the core.

Likewise, the required AC audio signal current can be determined by assuming that its peak value should be about 10 to 20 times the bias current. In the derivation of the inductance value above, the reactance at most audio frequencies can be neglected as the current will be mostly determined by the load resistance, R (item 9.c in FIG. 9). The signal voltage, which will be required, is simply the product of the required RMS AC current and the load resistance. The RMS AC current can be safely taken to be 0.71 multiplied by the peak AC current.

All of the above leads to an iterative calculation to determine the core size. Since the inductive reactance is small compared to the load resistance, there will not be much voltage developed across the winding. Since one expression for AC flux density is: B=(Vrmsx10E8)/(4.44 nFA_{E}) where:

Vrms=applied AC voltage across the winding in Volts

n=number of turns

F=frequency of the applied AC voltage in Hz

A_{E}=effective magnetic cross-sectional area of the core in square cm

it would appear that the cross-section of the core is important. In fact, the applied voltage across the winding is due to the AC current times X_{L}, and will be small. On the other hand, since B=uH as above, in this case H is due to ΔI, and ΔI=the RMS value of the peak AC signal current derived above (Ipkac). H=(nIpkac)/(0.8 Le). The total magnetizing force will be the sum of H due to the DC bias current and H due to the AC signal current. Thus, the effective magnetic path length of the core dominates. The resulting total flux density, B, should approach the rated saturation flux density for the core material at the highest AC signal level, which is to be processed. In a preferred embodiment, the physical implementation of the inductor should employ a toroidal core in the case of Molypermalloy, powdered iron or amorphous metal, or a pot core in the case of ferrite. This construction will give the best immunity to external magnetic fields, which could otherwise induce extraneous noise.

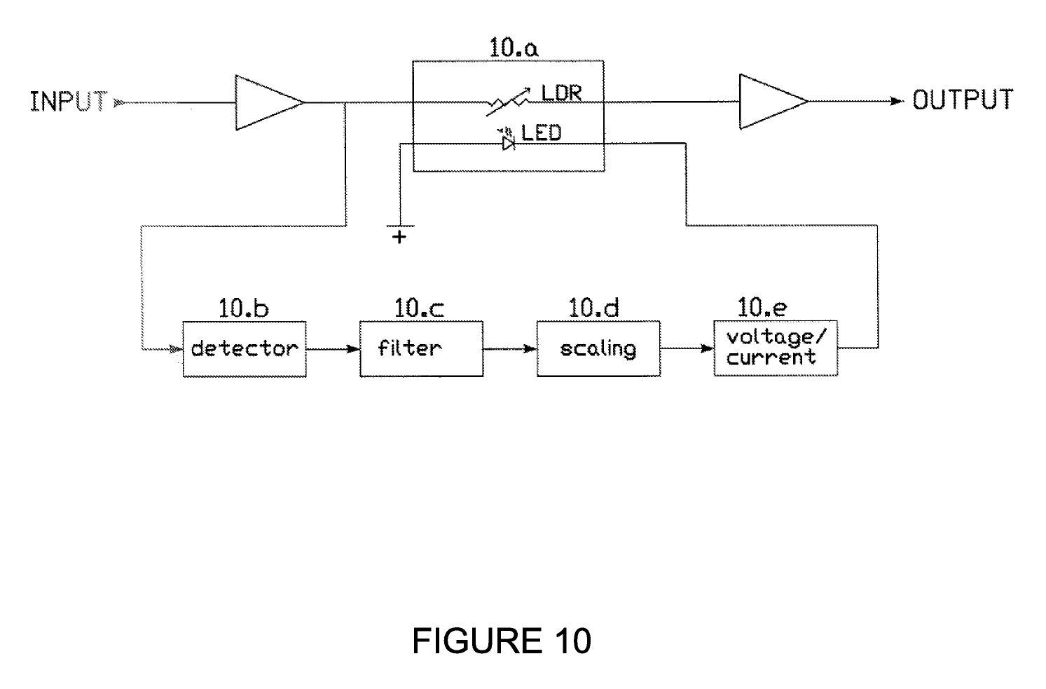

FIG. 10 shows a circuit which can be added to the signal path after the spectral modification circuit (described above) to counteract an undesired property of either the diode string or the inductor implementation of the nonlinear element. The desired asymmetry is imparted to the audio signal by effectively slightly “squashing” or “stretching” one polarity of the signal relative to the other. The net effect is a slight loss of energy at high signal levels compared to an unprocessed signal. Although the action is electrically instantaneous in the time domain, it is perceived in listening as an average loss of dynamics in loud passages. To counteract this effect, the added item in FIG. 10 is a signal expander. In an expander, the gain is proportional to the signal, i.e., the louder it gets, the louder it gets. In one embodiment of the instant invention, the expansion ratio is quite small being on the same order as the compression due to the nonlinear processes described above. This expander circuit responds to the average amplitude of the signal and operates with electrical symmetry. The result is that the average dynamic compression due to the nonlinear processes is compensated, but the asymmetry is not removed. Therefore the harmonic spectrum shaping is preserved and the dynamic energy is restored.

It should be noted that this technique can also be used to compensate the dynamic compression, which occurs in some loudspeakers due to heating of the voice-coil. In this application the circuit could be used separately or combined with spectral modification circuits of FIG. 9.

In one exemplary embodiment, the variable gain element, 10.a, is current-controllable and consists of a co-packaged light source and light dependent resistor (LDR). The LDR resistance varies inversely to the illumination from the light source which is typically a light emitting diode (LED) but which can also be an incandescent or electroluminescent device. In the case of the LED, the resistance value of the LDR will be inversely proportional to the current through the LED. The signal detector, 10.b, can detect either the average or the root-mean-square value of the input signal. Average detection is done with a precision rectifier circuit well known in the art, the output of which is averaged in a resistor-capacitor network with a time constant appropriate to the desired speed of operation. If the detector has low output impedance and a circuit with high input impedance buffers the voltage on the capacitor, then the attack and release times of the circuit will be symmetrical. Typical attack and release times are on the order 50 milliseconds. This is a sufficient arrangement for most applications. RMS (root-mean-square) detection can also be used but has been found to be subjectively less effective than average detection. Peak detection is also possible as a variation of the precision rectifier circuit using well-known circuit design techniques. It can be argued that peak detection may be more appropriate since it is the signal peaks, which need to be “uncompressed.” Whatever detection method is used, the result must be post-filtered, 10.c to achieve the desired slow time constants. The post filtered voltage from the detector circuit is buffered and scaled as required, 10.d, to control the variable gain element, 10.a. Where the variable gain element is current-controlled, the voltage from the detector may converted to a current, 10.e, using well known techniques.

In yet another embodiment, the present invention seeks to restore the perceptual and emotional elements lost to technical process of audio processing. This embodiment uses a psychoacoustic model to translate an encoded digital signal into data bands that are analyzed for harmonic significance. Then, a frequency analysis is performed and sections of sound that are deficient in harmonic quality are identified. The sections are analyzed for their fundamental frequency and amplitude. Additional signals of higher order harmonics for the sections are created and the higher order harmonics are added back to coded signal to form a newly enhanced signal which is inverse filtered and converted to an analog waveform for consumption by the listener.

Common digital audio standards such as MPEG-1 (Layers I-III), MPEG-2, Microsoft Windows Media audio, PAC, ATRAC, and others use a variety of encoding techniques to quantize and produce digital representations of analog acoustic sources. The sampling and encoding of audio is performed according to complex psychoacoustic models of human auditory perception in conjunction with data reduction schemes to produce a coded audio signal which can be decoded with less sophisticated circuitry to produce a stereophonic audio signal. Limitations bandwidth and bit rate requirements for the storage and transmission of digital data dictate the use inherently lossy coding algorithms. The purpose of the psychoacoustic model is to take advantage of the fact that the human auditory system can detect sound information up to certain thresholds and the presence of certain sounds can influence the ability of the brain to detect and perceive other sounds. The overall amount of data can be reduced by not encoding the audio signals that would be masked from the perception of the listener. For this reason, this family of encoding schemes is referred to as perceptual encoding.

Perceptual coding commonly works by separating an incoming audio signal into groups of bands that are compared to the psychoacoustic model. Those signals that are above the auditory threshold are quantized and passed through the encoding chain. The signals below the masking threshold are discarded, and all information from those samples is destroyed. The net effect is a final audio signal that is representative of the original analog source but that is inherently incomplete. Some of the information that is lost in the perceptual coding processes is some of the most important information necessary to retain the richness of the original analog recording. One of the major reasons for the effect is the fact that most psychoacoustic models are created and tested using static, non-organic sounds such as steady sinusoidal tones. The tones are produced at varying amplitudes and frequencies to determine the clinical ranges of human audio perception. Models, however, do not incorporate the complex and often unpredictable response of the ear to complex changing stimuli such as musical recordings which incorporate the perception of several layers of harmonics. The resulting digital signals are often described as being technically precise, but lacking in perceptual depth.

The present invention is designed to enhance a pre-produced digital audio signal to produce a more musically convincing product for the listener. The digital damage done to the audio signal in the form of quantization noise, and the information lost during the original recording encoding, cannot be directly recovered during the decoding process. It is therefore necessary to create a set of processing techniques and algorithms that will work in conjunction with previously established decoding standards to produce a new enhanced output signal.

The DSP implementation involves the use of a harmonic analyzer to examine the existing encoded data. In order to minimize the amount of digital noise from further data conversions, the encoded data is reevaluated after the audio stream has passed through the demultiplexing and error checking processes of the decoder. The subbands of digital data are windowed and scaled at values appropriate for the harmonic analysis. A filterbank is applied to the newly reconstructed bands of data, and an enhanced audio signal is created.

The psychoacoustic analyzer dynamically examines the decoded subbands of data with adaptive sample windowing to account for the differences in window size necessary to accurately detect transient audio information and frequency dependent audio information. A buffer is used to store sequential window information for dynamic analysis. In each sample window, the fundamental frequency of the incoming signal is determined and a series of supplementary signals is created at multiples of the detected fundamental frequency. The supplementary signals have decreasingly large amplitudes as they are created. The original signal and the artificially created harmonic implements are merged together and placed in a buffer for distribution to inverse filterbanks for the final creation of the analog output signal.

The psychoacoustic model used in the harmonic analysis is designed based upon the responsiveness of the human ear to harmonic stimulation. For the sake of audio reproduction, the preferred embodiment of the new psychoacoustic model is to use musical influences as the test and effectiveness criteria for the design. In this psychoacoustic model, instead of using static, non-organic sounds such as steady sinusoidal tones, the complexity of musical influences are used and incorporates several layers of harmonics.

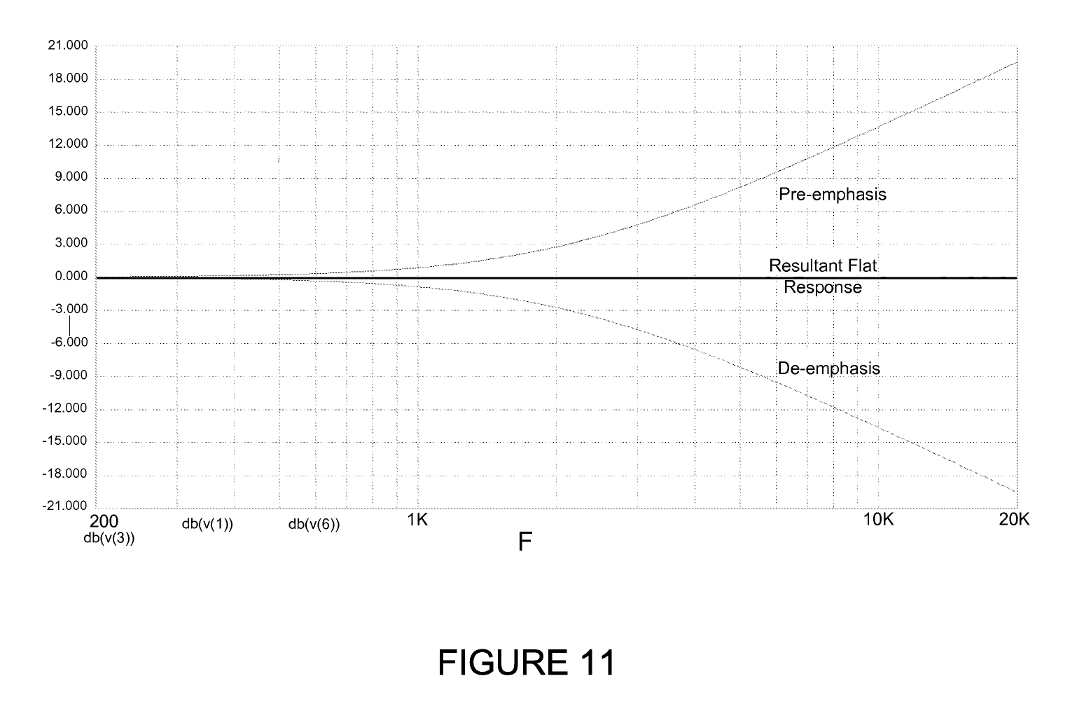

In yet another embodiment, an apparatus in accordance with the present invention performs a spectral modification of an analog audio signal in which the high-frequency content is reduced as a function of the signal amplitude and spectral distribution. The signal process is conceptually similar to what is used in cutting a LP disc record and playing it back, but without the record or the playback equipment. In general, the audio signal is subjected to a complementary pre-emphasis and de-emphasis of the high frequencies, as shown in FIG. 11. Also shown is the resulting flat frequency response.

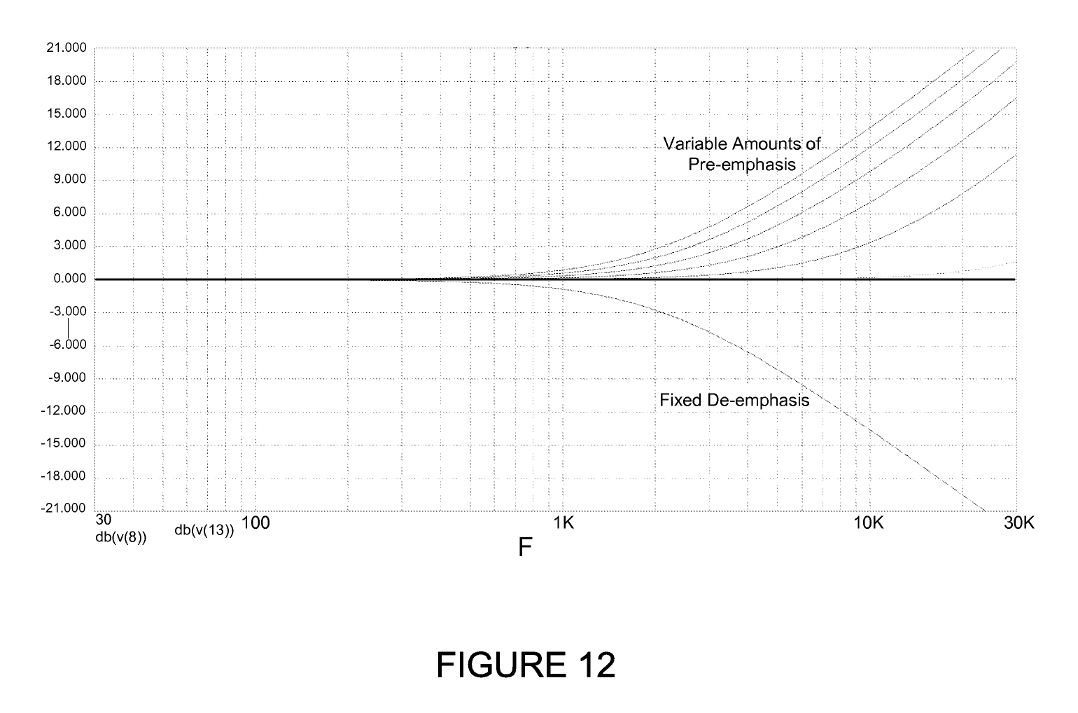

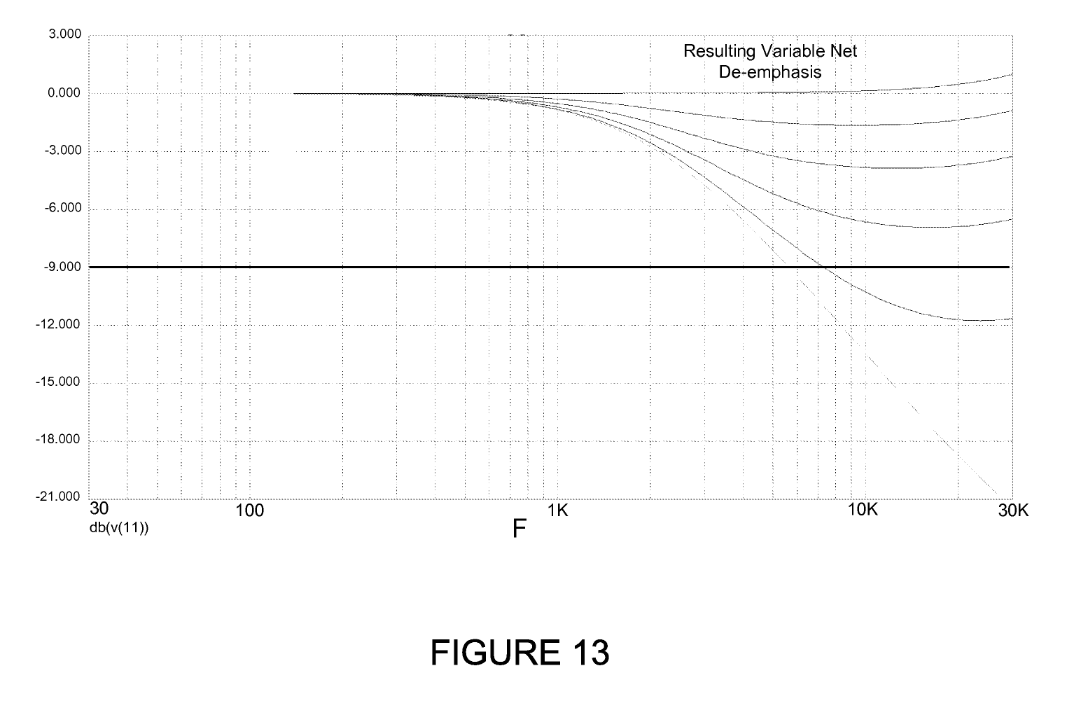

In FIG. 12, multiple pre-emphasis curves are shown along with the fixed de-emphasis. These multiple pre-emphasis curves constitute elements of a smooth continuum of downward adjustment of the pre-emphasis. The amount of downward adjustment (adaptation) of the pre-emphasis depends on the volume level and high-frequency content of the signal being processed. FIG. 13 shows the resulting output spectra as a result of the superposition of the adaptive pre-emphasis and the fixed de-emphasis.

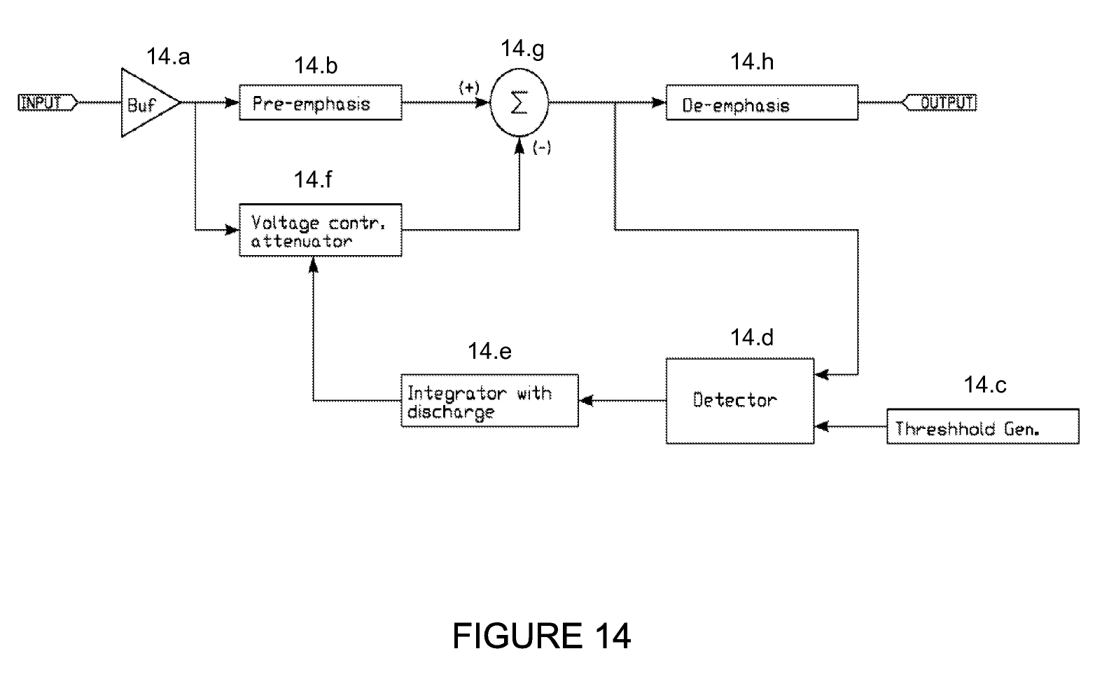

FIG. 14 shows the functional elements of an embodiment of the present invention in block diagram form. They comprise an input buffer amplifier (14.a), a pre-emphasis circuit (14.b), a threshhold voltage source (14.c), a peak-responding signal detector (14.d), an integrating circuit with discharge (14.e), an inverting voltage-controlled attenuator (14.f), a summing circuit (14.g), and a fixed de-emphasis circuit (14.h).

Because the basis of this invention is the energy disparity between the standardized LP record and newer digital media, in one embodiment the inflection time-constant, t, of the de-emphasis is chosen to be the same as for the LP, i.e., 75 microseconds. The frequency corresponding to this time-constant is F=½πT=2122 Hz. Thus, in the de-emphasis, frequencies above 2122 Hz are reduced in amplitude in dB according to 20 log 2122/Fx, where Fx is any frequency of interest above 2122 Hz. Strictly, the Laplace response function G(s)=ω/s+ω where s is the complex frequency variable (s=jω+ω) and ω=2π×2122 Hz=13333 radians/sec. However, there is no rigid technical reason for this choice of inflection frequency and another value could be instated if that were found to be preferable.

In the condition where the signal is below the threshold of the detector, the pre-emphasis is equal and opposite to the de-emphasis, or G=s/s+ω.

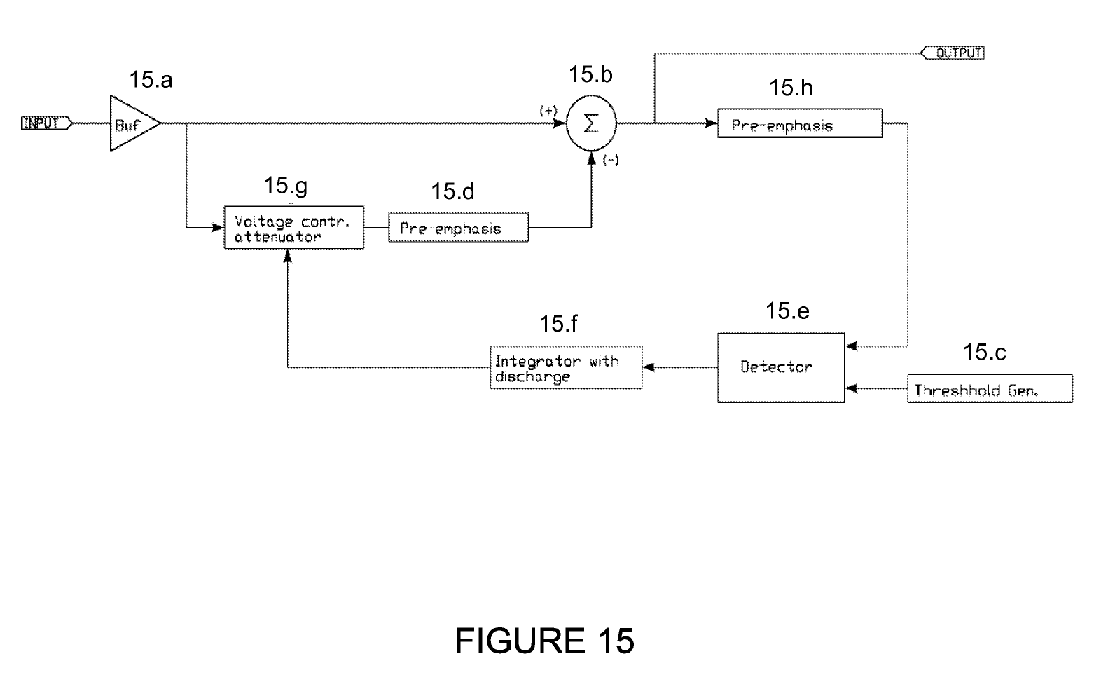

FIG. 15 shows an alternative embodiment of the invention, comprising an input buffer amplifier (15.a), a summing amplifier (15.b), a threshhold voltage source (15.c), a pre-emphasis circuit (15.d), a peak-responding signal detector (15.e), an integrating circuit with discharge (15.f), an inverting voltage controlled attenuator (15.g), and a pre-emphasis circuit (15.h). In this embodiment, the de-emphasis is the dependent variable and the pre-emphasis is in the control loop and is fixed.

This is potentially a more advantageous approach than that shown in FIG. 14 because the signal path from the input to the output contains no pre-emphasis, only de-emphasis. In the implementation of FIG. 14, the much more energetic pre-emphasized signal must be passed through several circuits. The signal in this form is more prone to causing distortion in the circuits. In the implementation of FIG. 15, only the control signal is subject to pre-emphasis. Moderate amounts of distortion in the control signal prior to detection will not influence the distortion of the output signal, only the accuracy of control. In either case, there is a feedback control arrangement. As a result, the control law of the voltage-controlled-amplifier is not critical.

The input buffer amplifier (15.a) may be arranged by anyone skilled in the art of circuit design. The variable filter comprises elements 15.b, 15.d and 15.g. FIG. 15 shows item 15.b as a summation with opposite arithmetic sign on the two inputs. This can be equally well accomplished if the voltage controlled attenuator is inverting and the summation polarities are the same.

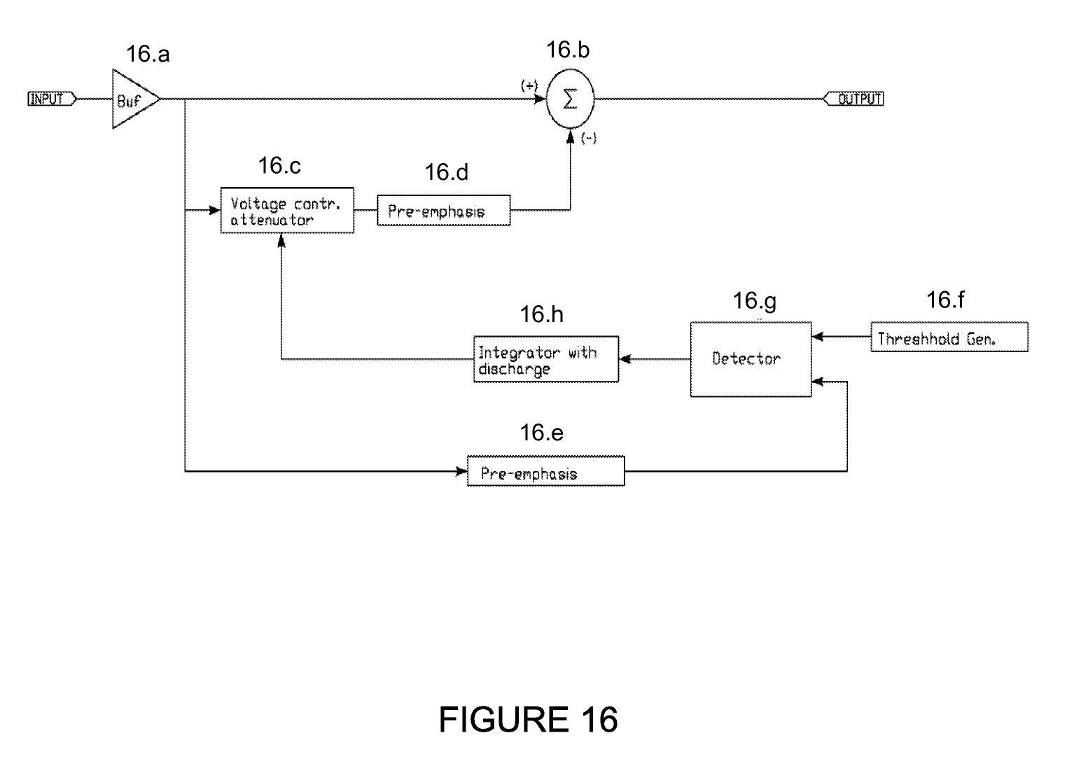

FIG. 16 shows a feed-forward control device and method. While this arrangement is possible, the law of both the detector and the voltage-controlled attenuator become critical as there is no feedback function to correct any control errors. The elements of FIG. 16 (16.a through 16.h) are essentially the same as in FIG. 14 and FIG. 15, but arranged differently.

The signal detector in the three embodiments shown is the same. It is a precision rectifier circuit whose output voltage is proportional to the amount by which the input voltage exceeds the reference voltage. The reference voltage is set to a value very slightly (about 1 dB) above the maximum value of the unpre-emphasized region of the signal. In this way, the (effective) de-emphasis is not triggered by low-frequency events. It should be noted that this process requires that the highest peak voltage of the un-preemphasized signal is known. Since these embodiments of the invention process digital signals, this is not a problem. In any digital system, the full-scale output voltage cannot be exceeded.

The output of the detector is then fed to an unsymmetrical time-averaging circuit. In this circuit, the peak value of the rectified signal is rapidly acquired and stored. When the voltage from the rectifer falls back, the stored value is allowed to decay at a controlled rate. In this way, the peak energy of the signal is extracted while minimizing ripple in the DC voltage. This is necessary so that the ripple component does not modulate the gain of the voltage-controlled attenuator at an audio rate. The exact (attack and release) time constants for this process are determined based on the psychoacoutic requirements. As a first order generalization, both the attack and release must be fairly rapid, typically around 100 microseconds attack and 1-2 milliseconds release.

The voltage controlled attenuator operates over an attenuation range of 0 dB to about −30 dB. Strictly, the maximum attenuation should be infinite to cause full pre-emphasis in the arrangement of FIG. 14 or no de-emphasis in the arrangement of FIG. 15. However, 30 dB is a practical number and brings the circuit within a small fraction of a dB of the ideal result.

A digital implementation of this process is also possible. In this case, the granularity of control needs to be carefully considered because the operation of the circuit is in a frequency region where the ear is quite sensitive to control artifacts.

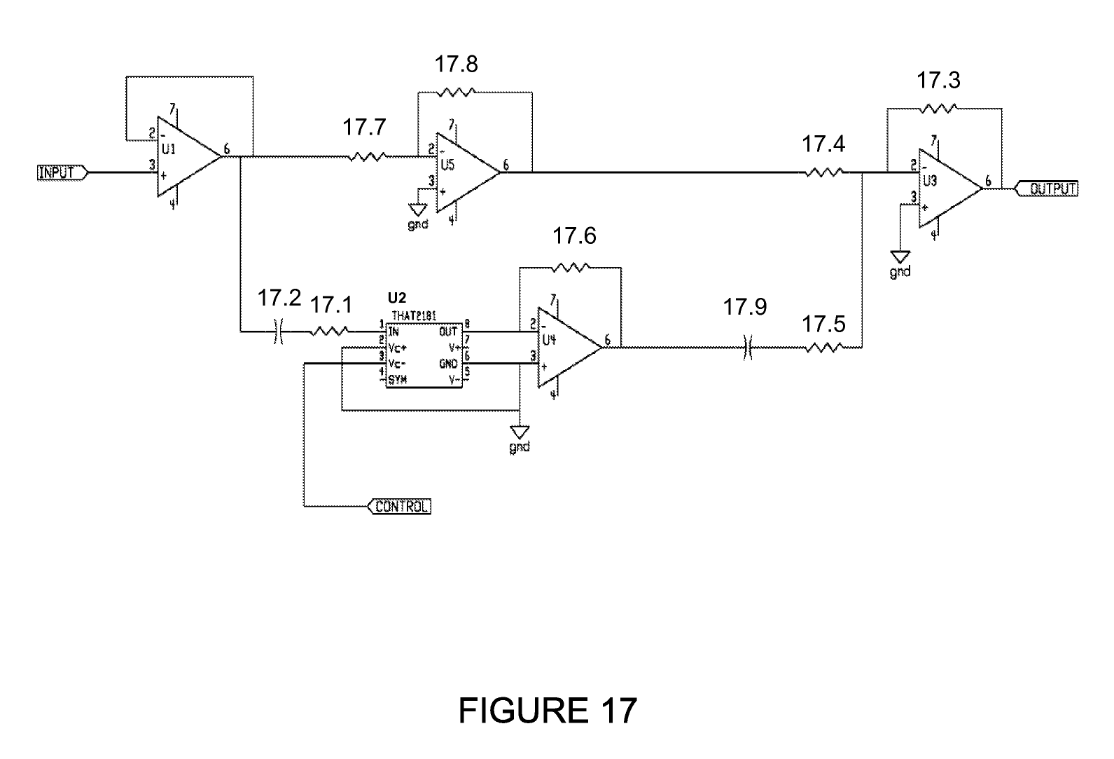

FIG. 17 shows an embodiment of an explicit circuit implementation of the de-emphasis filter using a commercially available voltage-controlled attenuator. The circuit implements the Laplace function G(s)=1−K(s/(s+ω)) where s is the complex frequency variable and ω=2πf. In the preferred embodiment f=2122 Hz, so ω=13333 radians/sec. If K=1, G(s)=75 usec full de-emphasis as shown in FIG. 11; if K=0, G(s)=flat response. It can be seen that the variable K controls the de-emphasis characteristic. In the circuit, K represents the linear attenuation ratio of the voltage controlled attenuator. Thus the circuit is a voltage controlled de-emphasis filter.

Buffer U1 is used to present a low source impedance to resistor 17.7 and RC network 17.1 and 17.2. Amplifier U5 in connection with resistors 17.7 and 17.8 is a unity-gain inverter. U2 is a voltage controlled attenuator which controls the ratio of input to output current according to the control voltage applied (as shown) to pin Vc−. Resistor 17.1 sets the input current and resistor 17.6 sets the output voltage from U4, so that the gain at zero control voltage=R(17.6)/R(17.2). Normally this equals 1. Resistor 17.5 and capacitor 17.9 create the (s-plane) zero represented by the term s/(s+w) in the transfer function. Their product=75 usec. Resistor 17.4 is set equal to resistor 17.5. Resistor 17.3 is set equal to resistor 17.4.

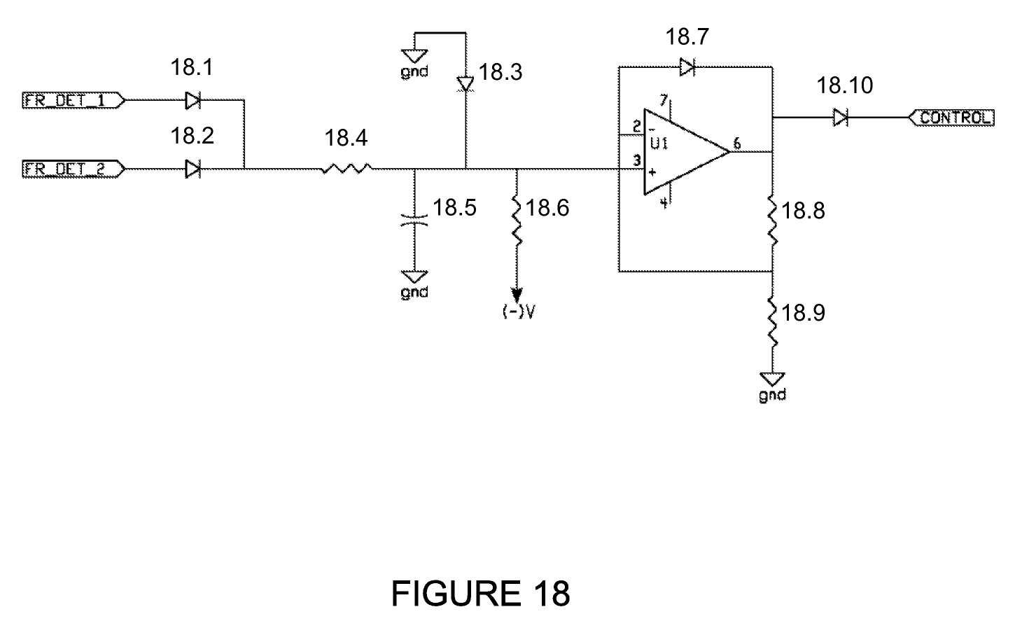

FIG. 18 shows an embodiment of the integrator with discharge. Two inputs are provided from two separate detectors, one for each channel of a 2-channel sterophonic source. More detectors are possible. Diodes 18.1 and 18.2 cause the higher of the two detector voltages to charge capacitor 18.5 via resistor 18.4. The acquisition of the peak value will occur logarithmically as 1−ê(t/T). The time constant T=the product of resistor 18.4 and capacitor 18.5. When the detector voltage falls below the voltage acquired on capacitor 18.5, the capacitor will discharge through resistor 18.6. By making the value of resistor 18.6 very large and returning it to a negative voltage, capacitor 18.5 is discharged by an essentially constant current at a rate i/C volts per second. Diode 18.3 prevents the input of U1 going more than 0.6V below ground. Diode 18.7 prevents the output of U1 from going below ground. Resistors 18.8 and 18.9 provide voltage gain if required for positive-going output from U1.

The choice of charge and discharge rates, along with the control law of the voltage-controlled attenuator have a strong effect on the audible performance. They need to be determined empirically. This can be done by one skilled in the art.

The resulting control voltage may need to be scaled and/or inverted to satisfy the control requirements of the voltage controlled attenuator. Because the control voltage is derived from the greater of the two inputs, it is used to operate the voltage-controlled attenuator (VCA) in both channels. In this way the channels are modified identically to each other, which is a necessary condition for stereophonic or multi-channel operation.

In one exemplary embodiment, the voltage-controlled-attenuator has a logarithmic control law in the form Gain=−6 mV/dB. Thus, for flat response the control voltage on the VCA has to be about 180 mV, which will give an attenuation of 30 dB or K=0.0316. As the control voltage rises, indicating the need for de-emphasis, the attenuation must be reduced until, in the limit, it is 0 dB or K=1. So the positive-going control voltage in FIG. 18 is scaled, offset and inverted. These processes are common and are not detailed here.

Thus, it should be understood that the embodiments and examples described herein have been chosen and described in order to best illustrate the principles of the invention and its practical applications to thereby enable one of ordinary skill in the art to best utilize the invention in various embodiments and with various modifications as are suited for particular uses contemplated. Even though specific embodiments of this invention have been described, they are not to be taken as exhaustive. There are several variations that will be apparent to those skilled in the art.

What is claimed is:

1. A method of modifying an audio signal, comprising the steps of:
receiving an audio signal;
subjecting the audio signal to a complementary pre-emphasis and de-emphasis of the high frequencies.

2. The method of claim 1, wherein the pre-emphasis is adjusted downward.

3. The method of claim 2, wherein the amount of downward adjustment is dependent upon the volume level and high-frequency content of the audio signal.

4. The method of claim 1, wherein the audio signal is analog.

5. The method of claim 1, wherein the audio signal is digital.

6. The method of claim 1, further comprising the step of outputting a modified audio signal.

7. A device for modifying an audio signal, comprising:
an input buffer amplifier;
a pre-emphasis circuit in electronic communication with the input buffer amplifier; and
an integrating circuit with discharge.

8. The device of claim 7, further comprising a threshold voltage source, and a peak-responding signal detector, and an inverting voltage-controlled attenuator.

9. The device of claim 8, further comprising a fixed de-emphasis circuit, and a summing circuit.

10. The device of claim 8, further comprising a second pre-emphasis circuit, and a summing amplifier.

11. The device of claim 8, wherein the signal detector is a rectifier circuit whose output voltage is proportional to the amount by which the input voltage exceeds the reference voltage.

12. The device of claim 8, wherein the reference voltage is set to a value slightly above the maximum value of the unpre-emphasized region of the audio signal being modified.
